(19) United States
(12) Patent Application Publication
(10) Pub. No.: US 2024/0321879 A1
(43) Pub. Date: Sep. 26, 2024

(54) STACKED LINEAR DOUBLE-LENGTH VTFETS

(71) Applicant: International Business Machines Corporation, Armonk, NY (US)

(72) Inventors: Brent A. Anderson, Jericho, VT (US); Ruilong Xie, Niskayuna, NY (US); Albert M. Chu, Nashua, NH (US); Nicholas Anthony Lanzillo, Wynantskill, NY (US); Reinaldo Vega, Mahopac, NY (US)

(21) Appl. No.: 18/188,042

(22) Filed: Mar. 22, 2023

(51) Int. Cl. H01L 27/088; H01L 21/8234; H01L 23/48; H01L 29/417; H01L 29/78

(52) U.S. Cl. CPC H01L 27/0886; H01L 21/823418; H01L 21/823475; H01L 23/481; H01L 29/41791; H01L 29/7851

(57) ABSTRACT

Semiconductor devices and methods of forming the same include a first layer including lower colinear vertical transfer field effect transistors (VTFETs). At least two of the colinear first VTFETs have a first shared bottom source/drain structure. A second layer is positioned over the first layer and includes upper colinear VTFETs. At least two of the upper colinear VTFETs have a second shared bottom source/drain structure.

### BACKGROUND

The present invention generally relates to semiconductor device fabrication and, more particularly, to vertical transfer field effect transistors (VTFETs) with improved device spacing.

As minimum feature sizes for semiconductor device fabrication technologies reach their physical limits, other approaches to increasing device density become important for improving the speed and power of new integrated circuits. VTFETs include channels that conduct current in a direction that is perpendicular to the surface of the underlying substrate, making it possible to create a higher number of devices within a given chip footprint.

Providing connections to VTFETs can be challenging, particularly when multiple such devices are connected in serial or in parallel. Due to their vertical orientation, connections may be needed on both the top side and bottom side of VTFETs, such that additional vias are needed to connect the devices to a common power or signal plane. These vias take up space that could otherwise be used for additional VTFETs, which decreases the device density.

### SUMMARY

A semiconductor device includes lower colinear vertical transfer field effect transistors (VTFETs). At least two of the colinear first VTFETs have a first shared bottom source/drain structure. A second layer is positioned over the first layer and includes upper colinear VTFETs. At least two of the upper colinear VTFETs have a second shared bottom source/drain structure.

A semiconductor device includes a first device and a second device. The first device includes first lower colinear vertical transfer field effect transistors (VTFETs) on a first layer. At least two of the first lower colinear VTFETs have a first lower shared bottom source/drain structure. The first device further includes first upper colinear VTFETs on a second layer positioned over the first layer. At least two of the plurality of first upper colinear VTFETs have a first upper shared bottom source/drain structure. The second device includes second lower colinear VTFETs on the first layer. At least two of the second lower colinear VTFETs have a second lower shared bottom source/drain structure. The second device further includes second upper colinear second VTFETs on the second layer. At least two of the second upper colinear VTFETs have a second upper shared bottom source/drain structure. A shared conductive via is positioned between the first device and the second device and connects electrically to the first device and to the second device.

A method of forming a s semiconductor device includes forming lower colinear vertical transfer field effect transistors VTFETs in a first device layer. At least two of the lower colinear VTFETs have a first shared bottom source/drain structure. A second device layer is bonded to the first device layer. Upper colinear VTFETs are formed in the second device layer, with at least two of the upper colinear VTFETs having a second shared bottom source/drain structure. A conductive via is formed through the first layer and the second layer that makes electrical contact with one of the lower colinear VTFETs and the upper colinear VTFETs.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a semiconductor device that includes pairs of vertical transfer field effect transistors (VTFETs) which share source/drain structures, in accordance with an embodiment of the present invention;

FIG. 2 is a side view of a semiconductor device that includes pairs of VTFETs which share source/drain structures, in accordance with an embodiment of the present invention;

FIG. 3 is a top-down view of a semiconductor device that includes a set of four VTFETs which share a source/drain structure, in accordance with an embodiment of the present invention;

FIG. 4 is a side view of a semiconductor device that includes a set of four VTFETs which share a source/drain structure, in accordance with an embodiment of the present invention;

FIG. 5 is a top-down view of a semiconductor device formed from pairs of VTFETs which share source/drain structures, in accordance with an embodiment of the present invention;

FIG. 6 is a side view of a semiconductor device formed from pairs of VTFETs which share source/drain structures, in accordance with an embodiment of the present invention;

FIG. 7 is a top-down view of an array of semiconductor devices that include pairs of VTFETs which share source/drain structures, in accordance with an embodiment of the present invention; and

FIG. 8 is a block/flow diagram of a method of forming a semiconductor device having pairs of VTFETs which share source/drain structures, in accordance with an embodiment of the present invention.

### DETAILED DESCRIPTION

The areal density of vertical transfer field effect transistors (VTFETs) may be increased by laying out such devices with most power/ground connections being connected to the back side of the device and with relatively sparse top power/ground connections passing through vias between the devices. By minimizing the number of top vias, the density of VTFETs can be improved. Additionally, relatively large bottom power/ground contacts may be used to reduce resistance and increase device performance.

For example, rather than having power/ground connection vias every two VTFETs, with such vias being shared between adjacent devices, the VTFETs may be laid out in pairs with a shared bottom source/drain structure. In such embodiments, four VTFETs may be served by a single top source/drain connection via, which improves the areal density—for example about 15% in some cases.

In addition to arranging connected VTFETs linearly along a single plane, multiple layers of such interconnected devices may be used. For example, a first layer may include devices having a first polarity type (e.g., n-type) and a second layer may be formed over the first layer with devices having a second polarity type (e.g., p-type). These devices may be connected to one another, for example with gate contact structures that extend between the layers. By determining which source/drain contacts are connected to which, and which gates are connected, different circuits can be implemented in a compact fashion. A variety of exemplary circuit layouts are shown herein to illustrate how the VTFETs may be arranged in practical devices.

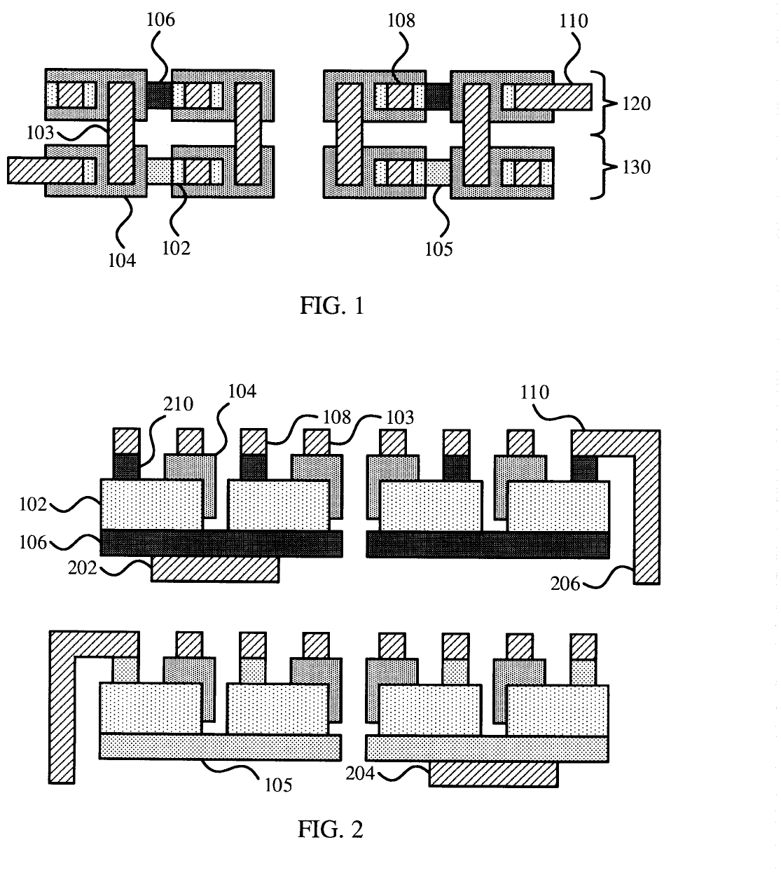

Referring now to FIG. 1, a top-down view of a set of VTFETs is shown. The devices are formed on channel fins 102, which may be formed from any appropriate semiconductor materials. Top devices 120 and bottom devices 130 are shown, and may be formed on different vertical levels of the device, as will be described in greater detail below. The top devices 120 may have a first polarity type (e.g., p-type) and the bottom devices 130 may have a second polarity type (e.g., n-type).

Each device may have a respective gate stack 104, each with a respective gate contact 103. The gate stack 104 may include a gate dielectric layer and work function metal layer as appropriate, and the gate contact 103 may be formed from any appropriate conductive material. As shown, the gate contact 103 may connect the gate stacks 104 of multiple VTFET devices. The gate contacts 103 may be connected to any appropriate top-side signal lines.

Adjacent VTFET devices may be connected to one another by a shared bottom source/drain, such as upper device source/drain 106 or lower device source/drain 105. Notably, each VTFET will have a respective top and bottom source/drain structure—the upper device source/drain 106 and the lower device source/drain 105 described herein both refer to the bottom source/drain structures for the respective upper devices 120 and lower devices 130. The shared source/drain structures 105/106 may be formed with appropriate dopants (e.g., p-type or n-type) to reflect the polarity of their respective devices. The shared source/drain structures 105/106 may further be arranged to connect a pair of VTFETs in series or in parallel, as will be illustrated in greater detail below. Additionally, although only pairs of devices are shown connected to one another in view, additional devices may be connected in parallel as well.

Topside source/drain contacts 108 make electrical contact to top source/drain structures on the VTFETs, connected to topside power or signal lines. Some bottom power/ground contacts 110 are formed that connect to vias, dropping down between the VTFETs. In this view the vias are positioned at the end linear series of VTFETs. However, the illustrated pattern of VTFETs may be repeated, with the vias serving devices on either side. In this manner, a single via or pair of vias may serve four VTFETs before needing to be repeated.

The illustrated devices represent a NAND and NOR device. On the left-hand side of the figure, a NAND gate may be formed by connecting the upper source/drain structure 106 to a power source, with the top VTFETs 120 being arranged in parallel with respect to a bottom power connection. The bottom VTFETs 130 for the left-hand side may be connected in series, with no power connection to the left-hand lower source/drain structure 105.

On the right-hand side of the figure, a NOR gate may be formed by connecting the lower source/drain structure 105 to ground, with the bottom VTFETs 130 being arranged in parallel with respect to a bottom ground connection. The top VTFETs 120 for the right-hand side may be connected in series, with no power or ground connection to the right-hand side upper source/drain structure 106.

As shown in this top-down view, the top devices 120 and the bottom devices 130 may be horizontally offset from one another. This horizontal offset makes it possible for the top devices 120 to have connections to underlying power lines without having to route around the bottom devices 130. The horizontal offset may be any appropriate value, for example being one half of the device pitch that would be used for devices on the same layer. The illustrated pattern of devices may be repeated in a tiling pattern, with additional devices being displaced laterally relative to the top devices 120 and the bottom devices 130, in a colinear fashion, and/or with additional devices being positioned parallel to and coplanar with the top devices 120 and the bottom devices 130. Additional devices may be separated from the illustrated devices at any appropriate device pitch, for example being dictated by the fabrication technology that is used, though it should be understood that the staggered positioning of the top devices 120 and the bottom devices 130 may cause the top devices 120 of one row to be closer to the bottom devices 130 of a next row than would be permissible if the devices were coplanar.

As noted above, the channel fins 102 may be formed from any appropriate semiconductor material. The channel fins 102 may be formed from a semiconductor substrate or device layer, formed from a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide.

The gate stack 104 is formed on a portion of the semiconductor channel fin 102. It should be understood that any appropriate composition and structure of the gate stack 104 may be used. As will be shown in greater detail below, the gate stack 104 may wrap around the channel fin 102 on one or more sides. The gate stack 104 may include a gate dielectric and a work function or contact metal, with the gate dielectric electrically insulating the work function metal and contact 103 from the body of the channel fin 102.

The gate dielectric of gate stacks 104 may be formed from any appropriate dielectric material, such as a high-k dielectric. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

The work function metal of gate stacks 104 may be formed from any appropriate p-type or n-type work function metal, corresponding to the polarity type of the respective device. As used herein, a “p-type work function metal” is a metal layer that effectuates a p-type threshold voltage shift. In one embodiment, the work function of the p-type work function metal layer ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the Fermi energy of a p-type semiconductor device towards a valence band of silicon in the silicon containing substrate of the p-type semiconductor device. A “valence band” is the highest range of electron energies where electrons are normally present at absolute zero. In one embodiment, the p-type work function metal layer may include titanium and/or its nitrides or carbides. In one embodiment, the p-type work function metal layer may include titanium nitride (TiN). The p-type work function metal layer may also or alternatively include TiAlN, Ru, Pt, Mo, Co or alloys or combinations thereof.

As used herein, an “n-type work function metal” is a metal layer that effectuates an n-type threshold voltage shift. “N-type threshold voltage shift” as used herein means a shift in the Fermi energy of an n-type semiconductor device towards a conduction band of silicon in a silicon-containing substrate of the n-type semiconductor device. The “conduction band” is the lowest lying electron energy band of the doped material that is not completely filled with electrons. In one embodiment, the work function of the n-type work function metal layer ranges from 4.1 eV to 4.3 eV. In one embodiment, the n-type work function metal layer is composed of at least one of TiAl, TanN, TiN, HfN, HfSi, or combinations thereof.

The gate contacts 103, source/drain contacts 108, and power/ground contacts 110 may be formed from any appropriate conductive material such as, e.g., tungsten, nickel, titanium, molybdenum, tantalum, copper, platinum, silver, gold, ruthenium, iridium, rhenium, rhodium, cobalt, and alloys thereof.

Lower device source/drains 105 and upper device source drains 106 may be formed from a doped semiconductor material. Doping involves adding dopant atoms to an intrinsic semiconductor, which changes the electron and hole carrier concentrations of the intrinsic semiconductor at thermal equilibrium. Dominant carrier concentration in an extrinsic semiconductor determines the conductivity type of the semiconductor. As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium. As used herein, “n-type” refers to the addition of impurities that contributes free electrons to an intrinsic semiconductor. In a silicon containing substrate, examples of n-type dopants, i.e., impurities, include but are not limited to antimony, arsenic and phosphorous.

The upper devices 120 and the lower devices 130 are described herein as differing in polarity type, but it should be understood that these groups of VTFETs may differ in other respects as well. For example, the two layers of devices may both have a same polarity type, but may differ in their semiconductor materials, work function metals, dopants, and/or other structural distinctions to produce devices having different electrical and semiconducting properties. The devices may further vary in their physical dimensions, for example having different channel lengths. Such structural differences may produce functional differences during operation, for example exhibiting differing voltage thresholds or current capacities.

Although two devices are shown, each being formed from a respective stacked set of pairs of VTFETs, it should be understood that embodiments using a single such device are also contemplated. For example, just the left-hand stack of VTFETs or the right-hard stack of VTFETs may be implemented in isolation. Furthermore, the devices need not necessarily be stacked vertically, so that a single coplanar pair of VTFETs is further contemplated.

Referring now to FIG. 2, a side view of a set of VTFETs is shown. This view illustrates the same VTFETs as are shown in FIG. 1, with upper devices 120 being shown on top and lower devices 130 being shown on bottom. Interlayer dielectric material is not shown, but should be understood to fill the space around and between the VTFETs, providing structural support and electrical insulation. Interconnections between the layers, such as the joined gate contacts 103 shown in FIG. 1, are not illustrated in FIG. 2 for the sake of simplicity. The gates of individual devices may or may not be connected to the gates of neighboring devices. The topside source/drain contacts 108 make electrical contact with top source/drain structures 210, which in turn contact the channel fins 102.

The arrangement of VTFETs is clear in this side view. On the left-hand side, the upper device source/drain 106 connects two VTFETs in parallel to an underlying power via 202. Not shown in this view is the underlying via 202 dropping down, behind the lower VTFETs 130, to make contact with an power line or plane. In contrast, the right-hand side shows an upper device source/drain 106 that connects two VTFETs in series. To supply power to these devices, power/ground contacts 110 are used that connect to a via 206 to the underlying power line or plane.

On the right-hand side, the lower device source/drain 105 connects two VTFETs in parallel to an underlying ground via 204. The underlying ground via 204 may connect to an underlying ground line or plane. In contrast, the left-hand side shows a lower device source/drain 105 that connects two VTFETs in series. To connect the series devices to ground, power/ground contacts 110 are used that connect to a via 206 to the underlying ground line or plane.

It should be understood that “power” and “ground” are used here to refer to the role these contacts play in the specific illustrated device configuration, and are not intended to be limiting. Different device configurations may reverse the power and ground designations, or may omit one or both entirely. Additionally, while the power and ground contacts 110 are illustrated as being connected to underlying power and ground lines or planes, it should be understood that they may equivalently be connected to overlying power or ground lines or planes. Some embodiments may have split power/ground sources, with the underlying vias 202 and 204 connecting to underlying power structures and with the power and ground contacts 110 connecting to overlying power or ground structures.

Serial and parallel arrangements of VTFETs are described herein. For example, on the left-hand side of FIG. 2, the upper pair of devices are arranged in a parallel arrangement. In the parallel arrangement, both VTFETs have a shared bottom structure that acts as, e.g., the source for both devices. As a result, parallel arrangement has contacts on the top and the bottom. On the right-hand side of FIG. 2, the upper pair of devices are arranged in a serial arrangement. In the serial arrangement, the shared bottom structure acts as the source for one VTFET of the pair and as the drain for the other VTFET of the pair. As a result, the serial arrangement has contacts on the top, with no contacts needed on the bottom of the devices.

The gate stacks 104 are shown as extending past the end surface of the fins 102. By making contact with the side surface of the fins 102, contact may be improved and the efficiency of the gate may be increased. In some embodiments, however, some or all of the gate stacks 104 may be formed to align with the end surface of the fins 102, such that the gate stacks 104 would not hang over the end of the fins 102.

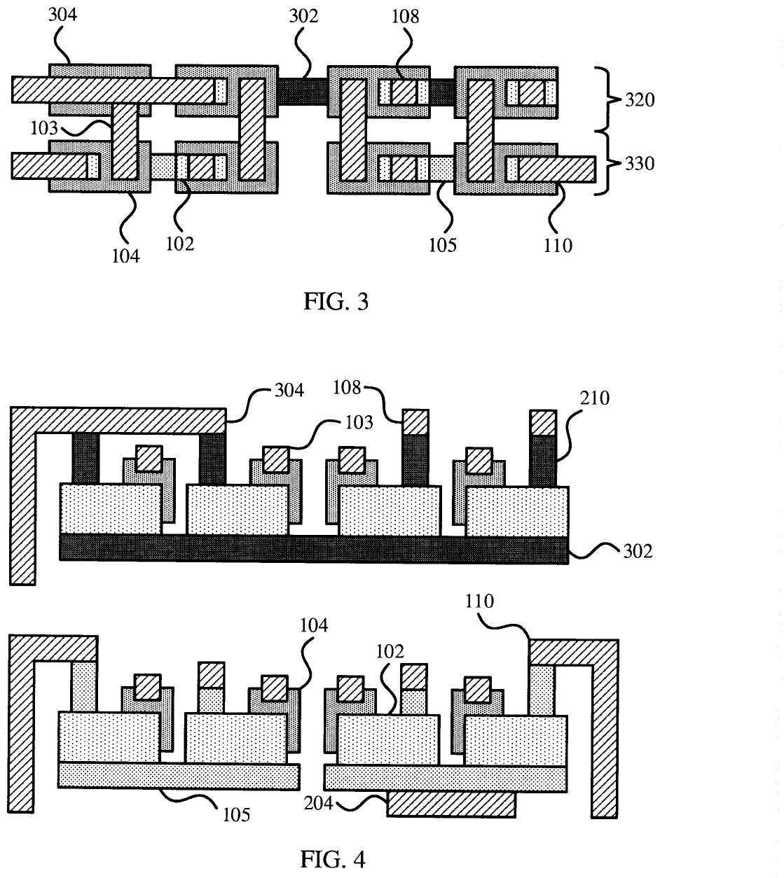

Referring now to FIG. 3, a top-down view of an AND-OR-invert 2-2 gate is shown. This device shows an embodiment that connects four VTFETs together with a shared bottom source/drain structure 302 on the upper devices 320. The gate of each upper device 320 is connected to the gate of a respective lower device 330, and power/ground contacts 110 are used as appropriate to connect to vias to an underlying power or ground structure. A shared power contact 304 connects two upper devices on the left-hand side before connecting to a via to the underlying power structure.

Referring now to FIG. 4, a side view of the AND-OR-invert 2-2 gate is shown. This view shows the two upper VTVETs on the left-hand side being connected in parallel to the shared power contact 304. The shared upper source/drain 302 is shown as contacting all four upper VTFETs. As noted above, the gate of each device in the upper layer are connected to the gate of a respective device in the lower layer, though that connection is not shown in this view. The heights of the gate contacts 103 on a given layer may be lower than the height of the shared power contact 302, so that the gate contact 103 can pass underneath the shared power contact 304.

FIG. 4 illustrates a particular arrangement of the upper devices 320 where the left-hand devices are connected in series with the right-hand devices. In such embodiments, the shared upper source/drain 302 acts as the source for one pair of devices and acts as the drain for the other pair of devices. While this particular arrangement is contemplated for the AND-OR-invert 2-2 gate, any appropriate arrangement of devices may be employed instead. For example, all four devices may be arranged in parallel, where the shared upper source/drain may act as a common source or drain for all four VTFETs. In another example, the shared upper source/drain may act as a source or drain for one of the four devices, and may act as the corresponding drain or source for the other three devices.

Referring now to FIG. 5, a top-down view of a pair of inverter devices is shown. The two VTFETs on the left-hand side form a first inverter and the two VTFETs on the right-hand side form a second inverter, with each pair including a VTFET from the upper devices 520 and a VTFET from the lower devices 530 that are connected by gate contact 103. As above, the upper devices 520 may be devices of a first polarity type (e.g., p-type VTFETs) and the lower devices 530 may be devices of a second polarity type (e.g., n-type VTFETs).

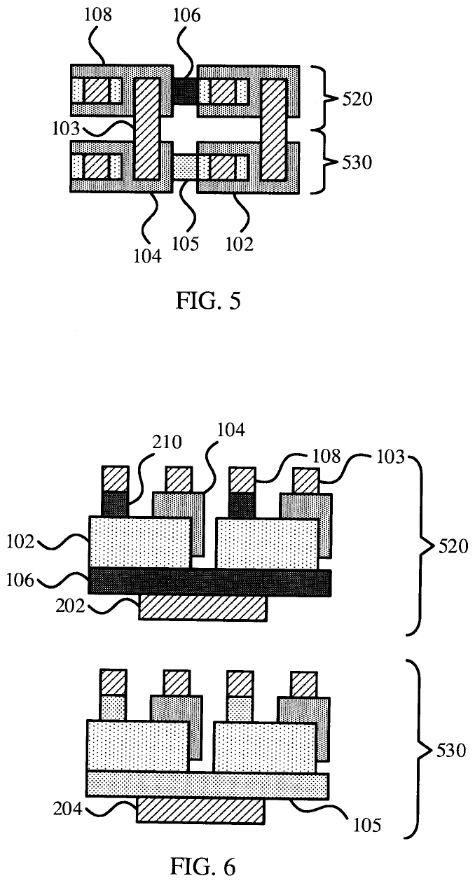

Referring now to FIG. 6, a side view of the pair of inverter devices is shown. The upper devices 520 are arranged in parallel with each other with respect to the upper device source/drain 106, while the lower device 530 are arranged in parallel with each other with respect to the lower device source/drain 105. As noted above, the gate contact 103 on the left-hand side connects the upper and lower left-hand devices to form a left-hand inverter and the gate contact 103 on the right-hand side connects the upper and lower right-hand devices to form a right-hand inverter.

The use of paired VTFETs, whether in a parallel or serial configuration, can therefore be used to form a variety of different logic components and circuits, such as the NAND, NOR, inverter, and AND-OR-invert 2-2 gate circuits described above. It should be understood that any appropriate multi-FET may be formed in this manner, with VTFETs being connected in parallel or series using a shared source/drain structure.

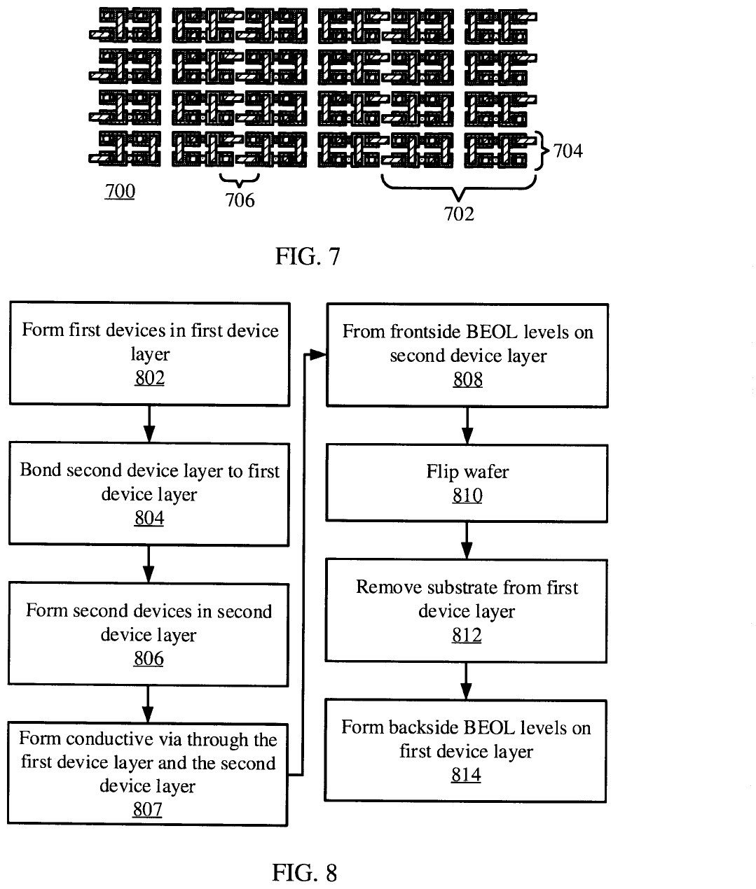

Referring now to FIG. 7, a top-down view of an array 700 of devices is shown. The array 700 is shown as being tiled in columns 702 and rows 704. While a rectangular array, such as shown in FIG. 7, is specifically contemplated, it should be understood that the rows 704 may have differing numbers of columns and that the columns 702 may have differing numbers of rows. In some cases, each tile of the array 700 may represent a same device or set of devices. For example, an array of logic gates may be formed to generate a memory device using NOR gates, NAND gates, or a combination of the two. In some cases, the tiles of the array 700 may differ from one another, with any appropriate devices and circuits being formed.

As noted above, the array 700 is formed on two planes, including an upper plane and a lower plane. Each tile of the array 700 may include devices on the upper plane and devices on the lower plane. The upper plane may include devices of a first polarity type (e.g., p-type) and the lower plane may include devices of a second polarity type (e.g., n-type).

There may be signal and power lines and planes above and/or below the planes of the array 700. Power lines and planes may include a positive supply voltage (e.g., V_{dd}) and a ground voltage (e.g., Vₛₛ). In some examples, power contacts may be positioned entirely below the array 700, entirely above the array 700, or both above and below the array 700. Signal lines are described herein as being positioned above the array 700, for example making contact with the top source/drain contacts and with the gate contacts of the VTFETs, but it should be understood that other embodiments are contemplated where some or all of the signal lines being positioned below the VTFETs. In some cases, the VTFETs and active planes described herein may be formed first, with power and signal lines and/or planes being formed in subsequent process steps.

In the illustrated array 700, the tiles connect to underlying power structures (e.g., V_{dd} or Vₛₛ) at vias that drop down between the tiles at position 706. In other embodiments, the vias may rise from the VTFETs to connect to overlying power structures. No such vias are needed within the tiles, so that the tile length can be reduced and chip area may be conserved. As shown in this view, neighboring tiles from adjacent columns 702 of the array may access a same underlying power structure at position 706.

Referring now to FIG. 8, a method of fabricating stacked liner double-length VTFETs is shown. Block 802 begins by forming first devices (e.g., VTFETs) in a first device layer. The first device layer may include a semiconductor substrate, into which are etched a set of semiconductor fins. Following the examples described above, two, four, or more such semiconductor fins may be formed in a single line along the semiconductor substrate. Block 802 may form any number of such sets of first devices, for example in a pattern to establish an array 700.

A bottom source/drain structure may be formed by, e.g., doping a portion of the semiconductor substrate underneath the semiconductor fin using a dopant of an appropriate polarity type (e.g., n-type). As described above, the bottom source/drain structure may contact two, four, or more of the semiconductor fins. In some cases, two bottom source/drain structures may be formed to contact respective pairs of colinear semiconductor fins. An upper source/drain structure may be formed on top of the semiconductor fin by any appropriate process, including any combination of epitaxial growth, masking, etching, and doping steps. Gate stacks may be formed in contact with respective semiconductor fins, for example by depositing a gate dielectric material and a layer of any appropriate work function metal.

Included in the formation of the first devices is the formation of contacts and vias through the first device layer. For example, any power contacts at the top of the VTFETs may pass through a via to access underlying structures that will be formed in subsequent processing steps. An interlayer dielectric material may be formed around the VTFETs and may be etched to form trenches and vias that provide electrical access to the source, drain, and gate structures of the VTFETs. Conductive material may be deposited in the trenches and vias to the relevant components of the VTFETs and to the surface of the first layer.

Block 804 bonds a second device layer to the first device layer, using any appropriate wafer bonding process to affix a second semiconductor layer. Block 806 forms second devices (e.g., VTFETs) in the second device layer. The second device layer may include a semiconductor substrate, into which are etched a set of semiconductor fins parallel to respective semiconductor fins of the first device layer, but offset in a direction perpendicular to the long dimension of the fins. As above, two, four, or more such semiconductor fins may be formed in a single line along the semiconductor substrate.

Included in the formation of the second devices is the formation of contacts and vias through the second device layer. An interlayer dielectric material may be formed around the VTFETs and may be etched to form trenches and vias that provide electrical access to the source, drain, and gate structures of the VTFETs. Conductive material may be deposited in the trenches and vias to the relevant components of the VTFETs and to the surface of the first layer. For example, interconnects may be formed between the first devices of the first layer and the second devices of the second layer, such as a shared gate contact. Block 807 forms a via that passes through both the second layer and the first layer, for example providing electrical connectivity to the overlying second layer from the back side of the first layer.

Block 808 forms one or more frontside back-end-of-line (BEOL) layers on the second device layer. The frontside BEOL layers may include any appropriate number of dielectric layers with respective sets of conductive material, such as interconnects and vias, to provide signal and/or power communication to contacts at the top surface of the second layer. The frontside BEOL layers may be formed in an iterative process, whereby a layer of dielectric material may be deposited and then may be patterned, forming trenches and vias. The trenches and vias may be filled with conductive material, and a chemical mechanical planarization (CMP) process may be used to polish the surface before a next BEOL layer is formed.

After formation of the frontside BEOL layer(s), block 810 flips the wafer over, so that the first layer is on top. Block 812 removes the semiconductor substrate from the first device layer by any appropriate process, such as a selective etch or CMP process. The removal of the semiconductor substrate may expose portions of the VTFETs, such as the bottom source/drain regions of the first devices. Block 814 then forms one or more backside BEOL layers on the exposed first layer. The formation of the backside BEOL layer(s) may include forming middle-of-line contacts to the backside structures of the first layer, for example including power contacts to some or all of the shared source/drain structures. Backside BEOL layers may then be formed sequentially on the backside of the first layer by iteratively depositing dielectric material, patterning the dielectric material to form trenches and vias, depositing conductive material in the trenches and vias, and polishing the surface to prepare for a next layer.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of stacked linear double-length VTFETs (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first layer including a plurality of lower colinear vertical transfer field effect transistors (VTFETs), with at least two of the plurality of lower colinear VTFETs having a first shared bottom source/drain structure; and
a second layer positioned over the first layer and including a plurality of upper colinear VTFETs, with at least two of the plurality of upper colinear VTFETs having a second shared bottom source/drain structure.

2. The semiconductor device of claim 1, wherein the lower colinear VTFETs have a first polarity type and the upper colinear VTFETs have a second polarity type.

3. The semiconductor device of claim 2, wherein the lower colinear VTFETs are n-type devices and the upper colinear VTFETs are p-type devices.

4. The semiconductor device of claim 1, wherein each of the upper colinear VTFETs includes a gate that is electrically connected to a gate of a respective lower colinear VTFET.

5. The semiconductor device of claim 1, wherein the upper colinear VTFETs include semiconductor channel fins that are parallel to semiconductor channel fins of the lower colinear VTFETs and that are laterally displaced in a direction that is perpendicular to a length of the semiconductor channel fins of the lower colinear VTFETs.

6. The semiconductor device of claim 1, wherein the shared bottom source/drain region of at least one of the lower colinear VTFETs and the upper colinear VTFETs includes a power contact that connects to a voltage source or to ground.

7. The semiconductor device of claim 1, wherein the shared bottom source/drain region of at least one of the lower colinear VTFETs and the upper colinear VTFETs has no power connection that connects to a voltage source or to a ground.

8. The semiconductor device of claim 1, wherein the plurality of lower colinear VTFETs includes a first set of four VTFETs and the plurality of upper colinear VTFETs includes a second set of four VTFETs.

9. The semiconductor device of claim 8, wherein at least one of the first shared bottom source/drain structure and the second shared bottom source/drain structure contacts one of the first set of four VTFETs or the second set of four VTFETs.

10. The semiconductor device of claim 9, wherein two of the second set of four VTFETs that share a bottom source/drain structure further include respective top source/drain structures that are electrically connected to one another.

11. The semiconductor device of claim 1, wherein the lower colinear VTFETs and the upper colinear VTFETs are connected to one another in such a way as to form a circuit selected from the group consisting of a NAND gate, a NOR gate, an inverter, and an AND-OR-inverter circuit.

12. The semiconductor device of claim 1, further comprising a conductive via that connects to a top source/drain structure of at least one of the upper colinear VTFETs and that passes through the first layer.

13. The semiconductor device of claim 1, wherein the lower colinear VTFETs and the upper colinear VTFETs include gate stacks that are aligned with ends of respective semiconductor fins.

14. A semiconductor device, comprising:
a first device that includes:
a plurality of first lower colinear vertical transfer field effect transistors (VTFETs) on a first layer, with at least two of the plurality of first lower colinear VTFETs having a first lower shared bottom source/drain structure; and
a plurality of first upper colinear VTFETs on a second layer positioned over the first layer, with at least two of the plurality of first upper colinear VTFETs having a first upper shared bottom source/drain structure;
a second device that includes:
a plurality of second lower colinear VTFETs on the first layer, with at least two of the plurality of second lower colinear VTFETs having a second lower shared bottom source/drain structure; and
a plurality of second upper colinear second VTFETs on the second layer, with at least two of the plurality of second upper colinear VTFETs having a second upper shared bottom source/drain structure; and
a shared conductive via positioned between the first device and the second device and that connects electrically to the first device and to the second device.

15. The semiconductor device of claim 14, wherein each of the lower colinear VTFETs includes a gate that is electrically connected to a gate of a respective upper colinear VTFET.

16. The semiconductor device of claim 14, wherein the upper colinear VTFETs of the first device and the second device include semiconductor channel fins that are parallel to semiconductor channel fins of the lower colinear VTFETs of the first device and the second device and that are laterally displaced in a direction that is perpendicular to a length of the semiconductor channel fins of the upper colinear VTFETs of the first device and the second device.

17. The semiconductor device of claim 14, wherein the conductive via that connects to a top source/drain structure of at least one of the upper colinear VTFETs of the first device or the second device and passes through the first layer.

18. A method of forming a semiconductor device, comprising:
forming a plurality of lower colinear vertical transfer field effect transistors (VTFETs) in a first device layer, with at least two of the plurality of lower colinear VTFETs having a first shared bottom source/drain structure; and
bonding a second device layer to the first device layer;
forming a plurality of upper colinear VTFETs in the second device layer, with at least two of the plurality of upper colinear VTFETs having a second shared bottom source/drain structure; and
forming a conductive via through the first layer and the second layer that makes electrical contact with one of the plurality of lower colinear VTFETs and the plurality of upper colinear VTFETs.

19. The method of claim 18, further comprising forming a conductive interconnect between one of the plurality of lower colinear VTFETs and one of the plurality of upper colinear VTFETs.

20. The method of claim 18, further comprising:
forming a frontside back-end-of-line (BEOL) layer on the second device layer;
flipping the first device layer and the second device layer; and
forming a backside BEOL layer on the first device layer.
